(19) United States
(12) Patent Application Publication
(10) Pub. No.: US 2026/0303094 A1
(43) Pub. Date: Oct. 1, 2026

(54) TOUCH SWITCH

(71) Applicant: MINEBEA MITSUMI Inc., Kitasaku-gun, Nagano (JP)

(72) Inventors: Izumi DOHI, Hiroshima (JP); Kazuyuki FUKUSHIMA, Hiroshima (JP); Shoya YAMAGUCHI, Hiroshima (JP)

(21) Appl. No.: 19/164,337

(22) PCT Filed: Feb. 21, 2024
(86) PCT No.: PCT/JP2024/006230

§ 371 Date: Sep. 11, 2025

(30) Foreign Application Priority Data
Mar. 16, 2023 (JP) 2023-042237

(51) Int. Cl. H03K 17/96; B60Q 3/82; G01D 5/24

(52) U.S. Cl. CPC H03K 17/9622; B60Q 3/82; G01D 5/24

(57) ABSTRACT

A touch switch includes an operation unit having a planar shape, a first sensor unit and a second sensor unit that allows detection of an approach of a human body to the operation unit by a change in capacitance, and a determination unit that determines that the operation unit has been operated. In the second sensor unit, a length in a direction in which the operation unit extends is longer than a length of the first sensor unit, and the determination unit determines that the operation unit has been operated when a time difference between a first time point at which the capacitance of the first sensor unit has changed and a second time point at which the capacitance of the second sensor unit has changed is equal to or longer than a predetermined determination time.

### TECHNICAL FIELD

The present invention relates to a touch switch.

### BACKGROUND ART

Patent Document 1 discloses a touch switch used for an indoor lamp disposed on a ceiling in a vehicle interior. The touch switch includes a capacitive sensor, and when a control unit detects a change in capacitance due to a touch operation by an occupant, the control unit switches between a lighting-on state and a lighting-off state of the indoor lamp.

### PRIOR ART DOCUMENT

### Patent Document

Patent Document 1: JP2013-84437 A

### SUMMARY OF THE INVENTION

### Problems to be Solved by the Invention

The touch switch of Patent Document 1 may malfunction due to, for example, irradiation of electromagnetic noise such as radio electric waves or radio waves of a mobile phone, and may erroneously determine that an occupant has performed an operation. This erroneous determination is presumed to be caused by an error in the detection of a capacitance caused by a noise voltage induced in a sensor electrode by the electromagnetic noise. Such erroneous determination at the time of irradiation of electromagnetic noise is not considered at all in Patent Document 1.

An object of the present invention is to provide a touch switch capable of preventing erroneous determination of an operation due to irradiation of electromagnetic noise.

### Solutions to the Problems

An aspect of the present invention provides a touch switch including an operation unit having a planar shape, a first sensor unit that allows detection of an approach of a human body to the operation unit by a change in capacitance, a second sensor unit that allows detection of approach of a human body to the operation unit by a change in capacitance and has a length in a direction in which the operation unit extends, the length being longer than a length in a direction in which the operation unit of the first sensor unit extends, and a determination unit that determines that the operation unit has been operated when a time difference between a first time point at which the capacitance of the first sensor unit has changed and a second time point at which the capacitance of the second sensor unit has changed is equal to or longer than a predetermined determination time.

The length of the second sensor unit in the direction in which the operation unit extends is longer than the length of the first sensor unit in the direction in which the operation unit extends. As a result, a detection range in a direction intersecting the planar operation unit is wider in the second sensor unit than in the first sensor unit. The speed at which electromagnetic noise approaches the operation unit is much faster than the speed at which an occupant brings the finger close to the operation unit for an operation purpose. Therefore, when the occupant operates the operation unit with the finger, the capacitance of the first sensor unit changes through a predetermined time difference after the capacitance of the second sensor unit changes. On the other hand, in a case where the electromagnetic noise is emitted, there is almost no time difference between the capacitance change of the second sensor unit and the capacitance change of the first sensor unit.

The determination unit determines that the operation unit has been operated when the time difference between the first time point at which the capacitance of the first sensor unit has changed and the second time point at which the capacitance of the second sensor unit has changed is equal to or longer than the predetermined determination time. That is, when the time difference between the first time point and the second time point is shorter than the determination time, it is determined that the malfunction is caused not by the operation of the operation unit by the finger but by the electromagnetic noise. It is therefore possible to prevent erroneous determination of an operation due to irradiation of electromagnetic noise.

### Effects of the Invention

The touch switch of the present invention can suppress erroneous determination of an operation due to irradiation of electromagnetic noise.

### BRIEF DESCRIPTION OF THE DRAWINGS

FIG. 1 is a bottom view of an indoor lamp using a touch switch according to an embodiment of the present invention;

FIG. 2 is an exploded perspective view of the indoor lamp in FIG. 1;

FIG. 3 is a front view illustrating a sensor unit in FIG. 2;

FIG. 4 is a sectional view taken along line IV-IV of FIG. 3;

FIG. 5 is a graph illustrating a human body and electromagnetic noise detected by one sensor;

FIG. 6 is a graph when a human body is detected by a detector in FIG. 3;

FIG. 7 is a graph when the detector in FIG. 3 is irradiated with electromagnetic noise;

FIG. 8 is a flowchart illustrating switching processing by a control unit; and

FIG. 9 is a front view illustrating a modification of the detector of the sensor unit.

### DETAILED DESCRIPTION

Hereinafter, embodiments of the present invention will be described with reference to the drawings.

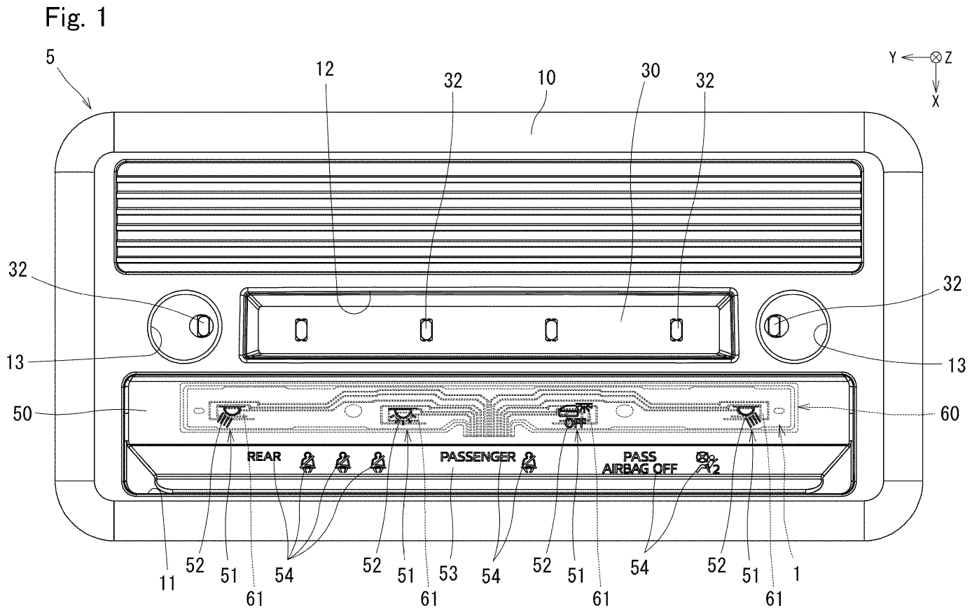

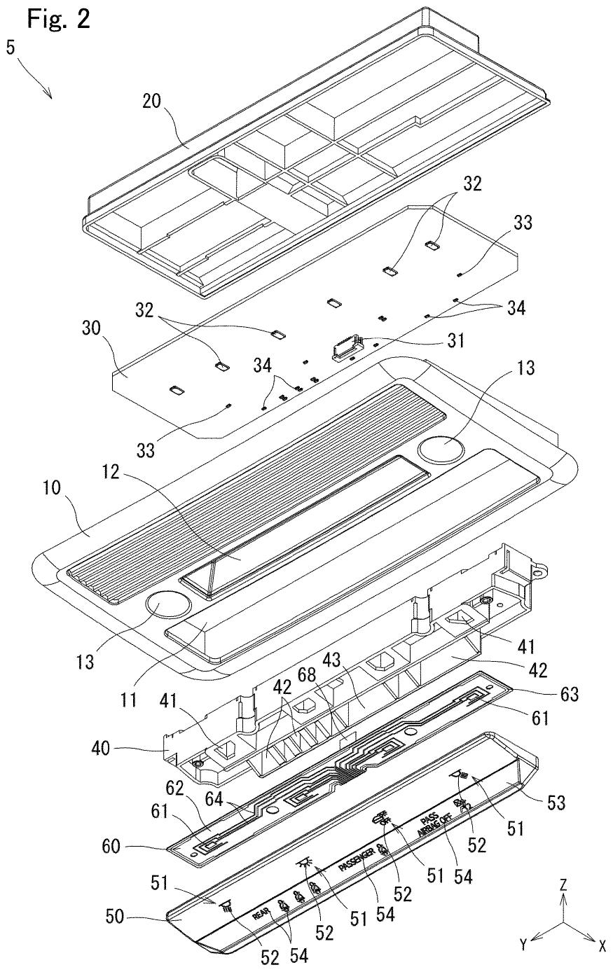

Referring to FIGS. 1 and 2, a touch switch 1 according to an embodiment of the present invention is used for an indoor lamp 5 disposed on a ceiling in a vehicle interior. First, an outline of the indoor lamp 5 will be described.

An X direction, a Y direction, and a Z direction in the accompanying drawings are a vehicle length direction, a vehicle width direction, and a vehicle height direction, respectively. Among the directions, the direction indicated by the arrow in the X direction is a front side, and the direction opposite to the arrow is a rear side.

The direction indicated by the arrow in the Z direction is an upper side (vehicle outer side), and the direction opposite to the arrow is a lower side (vehicle inner side).

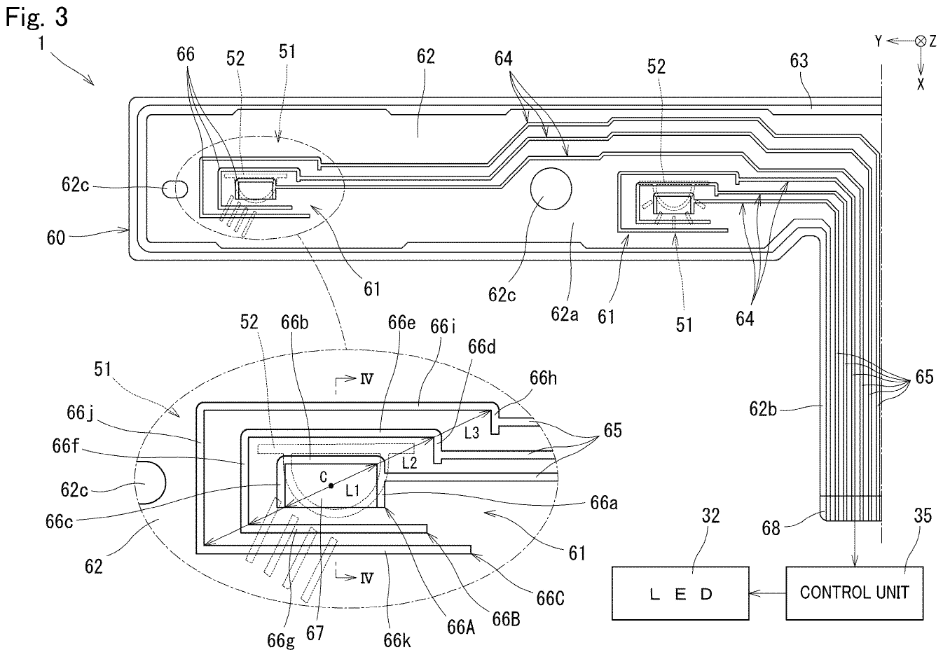

The indoor lamp 5 includes an exterior panel 10, a cover 20, a circuit board 30, a frame 40, an operation panel 50, and a sensor unit 60, and is disposed on the ceiling in the vehicle interior. Among the above, an operation unit 51 included in the operation panel 50, a detector 61 included in the sensor unit 60, and a control unit 35 (see FIG. 3) included in the circuit board 30 constitute the touch switch 1 according to the present embodiment.

The exterior panel 10 and the cover 20 are assembled to each other to form an outline of the indoor lamp 5. The circuit board 30 is disposed between the exterior panel 10 and the cover 20. The frame 40 and the operation panel 50 are assembled to an opening 11 of the exterior panel 10. The sensor unit 60 is disposed between the operation panel 50 and the frame 40.

The exterior panel 10 is molded with a resin having a light-shielding color, and is exposed to the vehicle inner side by attaching indoor lamp 5 to the vehicle. The exterior panel 10 is provided with the opening 11 for assembling the frame 40 and the operation panel 50. The exterior panel 10 is provided with a rectangular penetrating portion 12 and a pair of circular penetrating portions 13 in order to illuminate the vehicle interior.

The cover 20 is molded with a resin having a light-shielding color. The cover 20 is assembled to the upper side of the exterior panel 10, and is embedded in the ceiling by attaching the indoor lamp 5 to the vehicle. The cover 20 is provided with a cable insertion port (not illustrated) for connecting the circuit board 30 to the battery of the vehicle and an electronic control unit (ECU).

The circuit board 30 includes a connector 31 for connecting the sensor unit 60 and includes three types of LEDs 32 to 34 on a lower surface side facing the exterior panel 10. The LED 32 is provided to illuminate the vehicle interior through the penetrating portions 12 and 13 of the exterior panel 10. The LED 33 is provided to light a symbol mark 52 of the operation panel 50 through the penetrating portion 41 of the frame 40 and the sensor unit 60. The LED 34 is provided to light a mark 54 of the operation panel 50 through the penetrating portion 42 of the frame 40.

The circuit board 30 includes a connector (not illustrated) for connecting the battery and the ECU, a power supply circuit (not illustrated) for supplying power to the LEDs 32 to 34, and the control unit 35 (see FIG. 3) on an upper surface side facing the cover 20. The control unit 35 also has a function as a determination unit that determines whether the operation unit 51 has been operated. That is, the control unit 35 according to the present embodiment is a determination unit of the present invention. Note that the control unit 35 will be described in detail later.

The frame 40 is disposed in the opening 11 of the exterior panel 10 such that an end on the vehicle outer side abuts on the circuit board 30, and supports the operation panel 50. The frame 40 is provided with a plurality of penetrating portions 41 through which light emitted from the LED 33 passes and a plurality of penetrating portions 42 through which light emitted from the LED 34 passes. The plurality of penetrating portions 41 and 42 is provided so as to individually correspond to the marks 52 and 54 of the operation panel 50, respectively. The frame 40 is provided with a penetrating portion 43 through which a connecting portion 68 of the sensor unit 60 penetrates.

The operation panel 50 is assembled to the opening 11 of the exterior panel 10, and is exposed to the vehicle inner side by attaching the indoor lamp 5 to the vehicle.

In an intermediate portion of the operation panel 50 in the vehicle length direction, four operation units 51 corresponding to each of the LEDs 33 and each of the penetrating portions 41 of the frame 40 are provided. Each of the operation units 51 has a flat surface shape extending along an XY plane and is provided at an interval in the vehicle width direction. Each of the operation units 51 is provided with the symbol mark 52 indicating a switching function. The four symbol marks 52 are all different.

The operation panel 50 is provided, on the front side in the vehicle length direction, with a display unit 53 that displays cautions for the occupant. In the display unit 53, a total of eight marks 54 including symbols or characters are provided at intervals in the vehicle width direction. These marks 54 are different from each other, and are provided at positions corresponding to each of the LEDs 34 and each of the penetrating portions 42 of the frame 40.

The operation panel 50 configured as described above is formed by, for example, two-color molding. Specifically, the plurality of marks 52 and 54 is molded with a light-transmissive resin, and portions other than the marks 52 and 54 are molded with a light-shielding resin. As a result, only the corresponding marks 52 and 54 can be illuminated and lighted by causing the predetermined LEDs 33 and 34 to emit light.

Referring to FIGS. 2 and 3, the sensor unit 60 is disposed between the frame 40 and the operation panel 50, and is connected to the circuit board 30 by inserting the connecting portion 68 into the connector 31. The sensor unit 60 includes four detectors 61 corresponding to the operation units 51 of the operation panel 50, and detects approach of a finger of the occupant to the operation unit 51 by a change in capacitance. Specifically, the sensor unit 60 includes a capacitive film touch sensor, and includes a film base material 62, one ground electrode 63, and a plurality of conductor patterns 64.

The film base material 62 includes a light-transmissive and flexible resin. The film base material 62 has a T-shape and includes a rectangular base 62a extending in the vehicle width direction and a protrusion 62b protruding from a center of the base 62a in the vehicle length direction. A portion of the film base material 62 where the ground electrode 63 and the conductor pattern 64 are not disposed is provided with a positioning hole 62c for positioning at a fixed position between the frame 40 and the operation panel 50.

The ground electrode 63 includes a band-shaped flexible conductive plate, has both ends which are disposed at an end of the protrusion 62b of the film base material 62, and is wired along an outer peripheral edge of the film base material 62 so as to surround the plurality of conductor patterns 64.

The conductor pattern 64 includes a band-shaped flexible conductive plate, and is provided to form the detector 61. The conductor pattern 64 includes a connection wire 65 and a self-capacitance type sensor electrode 66 constituting the detector 61. In the present embodiment, one detector 61 is configured by the sensor electrode 66 of each of three conductor patterns 64. Since the four detectors 61 are provided, a total of twelve conductor patterns 64 are used.

The connection wire 65 extends from the end of the protrusion 62b of the film base material 62 to a predetermined one of the four detectors 61. All the connection wires 65 are provided at different positions in the vehicle length direction and the vehicle width direction. The end of the protrusion 62b including an end of the connection wire 65 constitutes the connecting portion 68.

The sensor electrode 66 is continuous with the connection wire 65 and is disposed in a back portion of the operation unit 51. In FIGS. 1 and 2, the two left detectors 61 configured by the three sensor electrodes 66 have substantially the same shape, and the two right detectors 61 in FIGS. 1 and 2 are symmetric with the two left detectors 61.

The touch switch 1 includes the operation unit 51 included in the operation panel 50, the detector 61 included in the sensor unit 60, and the control unit 35 included in the circuit board 30. The number of the detectors 61 may be one or plural as in the present embodiment.

Hereinafter, the three sensor electrodes 66 constituting one detector 61 will be specifically described with reference to FIG. 3.

In the following description, among the three sensor electrodes 66 constituting the one detector 61, one of the sensor electrodes 66 located on an innermost side may be referred to as a first sensor electrode (first sensor unit) 66A, one of the sensor electrodes 66 adjacent to an outer side of the first sensor electrode 66A may be referred to as a second sensor electrode (second sensor unit) 66B, and one of the sensor electrodes 66 located on an outermost side may be referred to as a third sensor electrode (third sensor unit) 66C.

The first sensor electrode 66A, the second sensor electrode 66B, and the third sensor electrode 66C are all provided to detect approach of a human body to the operation unit 51 by a change in capacitances C1 to C3. Each of these sensor electrodes 66A to 66C has a rectangular shape whose dimension in the vehicle width direction is longer than the dimension in the vehicle length direction. These sizes (areas) are the smallest in the first sensor electrode 66A and the largest in the third sensor electrode 66C.

The sensor electrodes 66A to 66C are arranged at opposing positions behind the operation unit 51, specifically, behind the symbol mark 52. A centroid C of each of the sensor electrodes 66A to 66C including a center of the operation unit 51 and a center of the symbol mark 52 coincides in the vehicle length direction and the vehicle width direction. However, the centroids C of the sensor electrodes 66A to 66C do not have to coincide in a geometrically strict sense, and the centroids C of the remaining sensor electrodes 66A and 66B are only required to be located in the largest third sensor electrode 66C.

The first sensor electrode 66A has an open-ended shape substantially surrounding the center of the operation unit 51, and extends along the XY plane similarly to the operation unit 51. The first sensor electrode 66A includes a first portion 66a continuous with the connection wire 65 and extending in the vehicle length direction, a second portion 66b continuous with the first portion 66a and extending in the vehicle width direction, and a third portion 66c continuous with the second portion 66b and extending in the vehicle length direction. A position facing the second portion 66b is open.

In the first sensor electrode 66A, a conductive portion 67 having a flat planar shape is provided by printing a transparent conductive ink. An outer peripheral edge of the conductive portion 67 is in contact with an inner peripheral edge of the first sensor electrode 66A, and electrical conduction therebetween is established.

The second sensor electrode 66B has an open-ended shape substantially surrounding the first sensor electrode 66A, and extends along the XY plane similarly to the operation unit 51. The second sensor electrode 66B includes a first portion 66d continuous with the connection wire 65 and extending in the vehicle length direction, a second portion 66e continuous with the first portion 66d and extending in the vehicle width direction, a third portion 66f continuous with the second portion 66e and extending in the vehicle length direction, and a fourth portion 66g continuous with the third portion 66f and extending in the vehicle width direction. In FIG. 3, a space between a lower end of the first portion 66d and a right end of the fourth portion 66g is open. The connection wire 65 continuous with the first sensor electrode 66A is wired through this open portion.

In FIG. 3, the first portion 66d is located at an interval on the upper right side of the first portion 66a of the first sensor electrode 66A. In FIG. 3, the second portion 66e is located above the second portion 66b of the first sensor electrode 66A at an interval. In FIG. 3, the third portion 66f is located on the left side of the third portion 66c of the first sensor electrode 66A at an interval. In FIG. 3, the fourth portion 66g is located below a lower end of the first portion 66a and a lower end of the third portion 66c of the first sensor electrode 66A with an interval. In the second sensor electrode 66B, a conductive portion is not provided unlike the first sensor electrode 66A.

The third sensor electrode 66C has an open-ended shape substantially surrounding the second sensor electrode 66B, and extends along the XY plane similarly to the operation unit 51. The third sensor electrode 66C includes a first portion 66h continuous with the connection wire 65 and extending in the vehicle length direction, a second portion 66i continuous with the first portion 66h and extending in the vehicle width direction, a third portion 66j continuous with the second portion 66i and extending in the vehicle length direction, and a fourth portion 66k continuous with the third portion 66j and extending in the vehicle width direction. In FIG. 3, a space between a lower end of the first portion 66h and a right end of the fourth portion 66k is open. Two connection wires 65 continuous with each of the first sensor electrode 66A and the second sensor electrode 66B are wired through this open portion.

In FIG. 3, the first portion 66h is located at an interval on the upper right side of the first portion 66d of the second sensor electrode 66B. In FIG. 3, the second portion 66i is located above the second portion 66e of the second sensor electrode 66B at an interval. In FIG. 3, the third portion 66j is located on the left side of the third portion 66f of the second sensor electrode 66B at an interval. In FIG. 3, the fourth portion 66k is located below the fourth portion 66g of the second sensor electrode 66B at an interval. In the third sensor electrode 66C, a conductive portion is not provided unlike the first sensor electrode 66A.

The lengths in the direction in which the sensor electrodes 66A to 66C configured as described above extend, specifically, a length L1 in a diagonal direction of the first sensor electrode 66A, a length L2 in a diagonal direction of the second sensor electrode 66B, and a length L3 in a diagonal direction of the third sensor electrode 66C become longer in that order. That is, the length L2 of the second sensor electrode 66B is longer than the length L1 of the first sensor electrode 66A, and the length L3 of the third sensor electrode 66C is longer than the length L2 of the second sensor electrode 66B (L1<L2<L3).

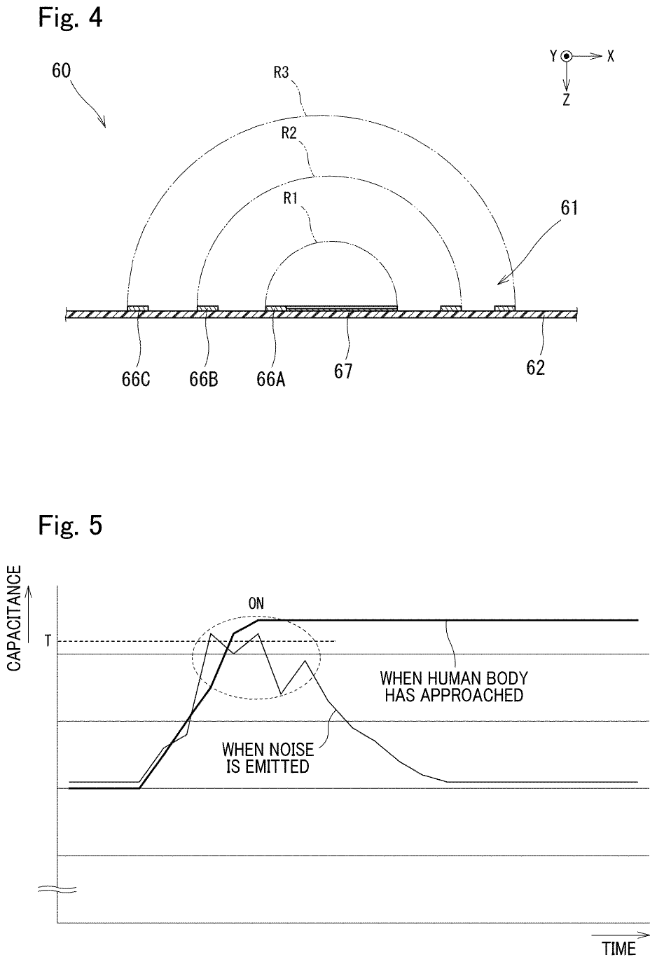

Referring to FIG. 4, ranges in which a human body can be detected by the sensor electrodes 66A to 66C (hereinafter referred to as “detection ranges”) R1 to R3 are widened in the order of the detection range R1 of the first sensor electrode 66A, the detection range R2 of the second sensor electrode 66B, and the detection range R3 of the third sensor electrode 66C (R1<R2<R3). This is because the detection ranges R1 to R3 of the sensor electrodes 66A to 66C correspond to the lengths L1 to L3 of the sensor electrodes 66A to 66C. That is, in the present embodiment, the three-stage detection ranges R1 to R3 are set by the three sensor electrodes 66A to 66C. Since each of the sensor electrodes 66A to 66C has a rectangular shape when viewed from the vehicle height direction, each of the detection ranges R1 to R3 has a substantially semi-elliptical spherical shape.

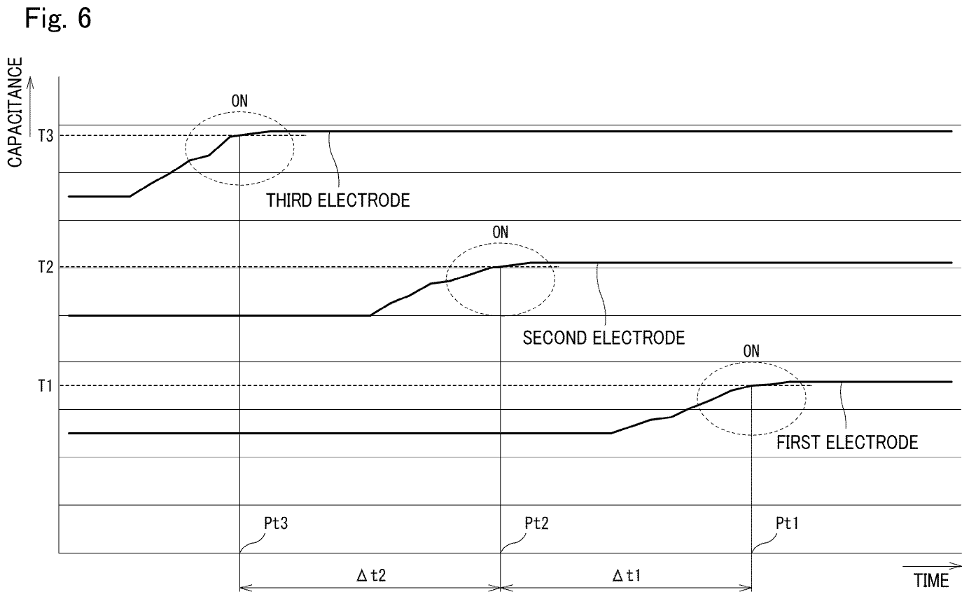

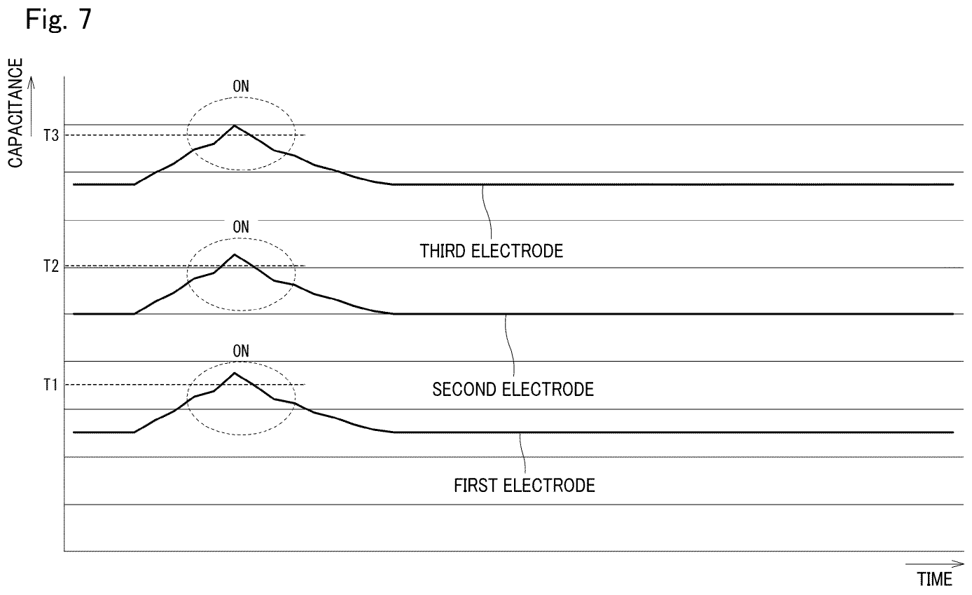

FIG. 5 is a graph in which a change in capacitance C in a case where a human finger approaches the detector 61 including one sensor electrode 66 and a change in capacitance C in a case where electromagnetic noise is emitted are superimposed. FIG. 6 is a graph illustrating changes in the capacitances C1 to C3 in a case where the detector 61 including the three sensor electrodes 66A to 66C detects a human finger, and FIG. 7 is a graph showing changes in the capacitances C1 to C3 in a case where the detector 61 including the three sensor electrodes 66A to 66C is irradiated with electromagnetic noise. In FIGS. 5 to 7, the vertical axis represents capacitance, and the horizontal axis represents time.

Referring to FIG. 5, when a human finger approaches the detector 61 including the one sensor electrode 66, the capacitance C generated between the sensor electrode 66 and the finger increases beyond a predetermined threshold value T, and this increasing state continues until the finger is released. On the other hand, when the finger is released, the capacitance C decreases to a state before the increase. On the other hand, when the detector 61 including the one sensor electrode 66 is irradiated with electromagnetic noise such as radio electric waves or radio waves of a mobile phone, the sensor electrode 66 is induced by the electromagnetic noise, so that the capacitance C increases beyond the predetermined threshold value T, and when the irradiation of the electromagnetic noise is eliminated, the capacitance C decreases to a state before the increase.

Referring to FIG. 6, when a human finger approaches the detector 61 including the three sensor electrodes 66A to 66C, the capacitances C1 to C3 generated between the sensor electrodes 66A to 66C and the finger increase beyond predetermined threshold values T1 to T3, respectively, and this increasing state continues until the finger is released. On the other hand, when the finger is released, the capacitances C1 to C3 decrease to a state before the increase. However, the detection ranges R1 to R3 of the three sensor electrodes 66A to 66C are also different depending on the differences in the lengths L1 to L3. Therefore, first, the capacitance C3 of the third sensor electrode 66C increases, and then the capacitance C2 of the second sensor electrode 66B changes through a time difference Δt2, and then the capacitance C1 of the first sensor electrode 66A further changes through a time difference Δt1.

On the other hand, referring to FIG. 7, when the detector 61 including the three sensor electrodes 66A to 66C is irradiated with electromagnetic noise, the capacitances C1 to C3 of the third sensor electrode 66C, the second sensor electrode 66B, and the first sensor electrode 66A increase exceeding the threshold values T1 to T3 determined almost without a time difference, and immediately decrease to the state before the increase. This is because the speed at which the electromagnetic noise approaches the sensor electrodes 66A to 66C is much faster than the speed at which the occupant brings the finger close to the sensor electrodes 66A to 66C for the operation purpose.

The control unit 35 includes a single or a plurality of microcomputers and other electronic devices. The control unit 35 also has a function as a determination unit, detects changes in the capacitances C1 to C3 of the sensor electrodes 66A to 66C, and determines whether the operation unit 51 has been operated. Then, when it is determined that the operation unit 51 is subjected to a touch operation, a function corresponding to the operation unit 51, that is, in the present embodiment, the LED 32 illustrated in FIG. 1 is switched between an on (lighting-on) state and an off (lighting-off) state. However, the control unit 35 may include an ECU mounted on the vehicle. The determination unit may include a single or a plurality of microcomputers and other electronic devices provided separately from the control unit 35.

The control unit 35 includes a memory and a timer (not illustrated). The memory stores determination times Jt1 and Jt2 for determining whether an operation is performed by the occupant or a malfunction due to electromagnetic noise. The first determination time Jt1 is set to compare the time difference Δt1 between a first time point Pt1 at which the capacitance C1 of the first sensor electrode 66A has changed and a second time point Pt2 at which the capacitance C2 of the second sensor electrode 66B has changed. The second determination time Jt2 is set to compare the time difference Δt2 between the second time point Pt2 at which the capacitance C2 of the second sensor electrode 66B has changed and a third time point Pt3 at which the capacitance C3 of the third sensor electrode 66C has changed. Here, a time point Pt at which the capacitance C of the sensor electrode 66 changes means a time point at which the capacitance C exceeds a predetermined threshold value T.

Specifically, the control unit 35 determines whether the time difference Δt2 between the change in the capacitance C3 of the third sensor electrode 66C and the change in the capacitance C2 of the second sensor electrode 66B is equal to or longer than the determination time Jt2 (for example, 20 ms) or shorter than the determination time Jt2. The control unit 35 determines whether the time difference Δt1 between the change in the capacitance C2 of the second sensor electrode 66B and the change in the capacitance C1 of the first sensor electrode 66A is equal to or longer than the determination time Jt1 (for example, 20 ms) or shorter than the determination time Jt1. In a case where both the time differences Δt1 and Δt2 are equal to or longer than the determination times Jt1 and Jt2, it is determined that the touch operation is performed by the occupant, and the display state of the LED 32 is switched. On the other hand, in a case where any one of the time differences Δt1 and Δt2 is less than the determination times Jt1 and Jt2, it is determined that a malfunction is caused by electromagnetic noise, and the display state of the LED 32 is not switched.

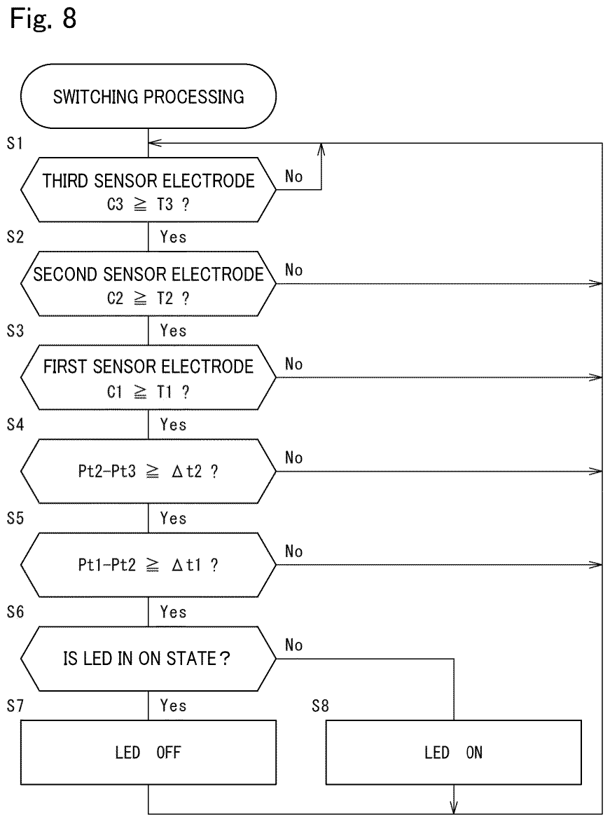

Next, switching processing of the indoor lamp 5 by the control unit 35 will be specifically described with reference to FIG. 8.

In step S1, the control unit 35 waits until the capacitance C3 of the third sensor electrode 66C becomes equal to or greater than the threshold value T3, and when the capacitance C3 becomes equal to or greater than the threshold value T3, in step S2, the control unit determines whether the capacitance C2 of the second sensor electrode 66B becomes equal to or greater than the threshold value T2. Then, in a case where the capacitance C2 is less than the threshold value T2, the processing returns to step S1, and in a case where the capacitance C2 is equal to or greater than the threshold value T2, the processing proceeds to step S3. In step S3, it is determined whether the capacitance C1 of the first sensor electrode 66A is equal to or greater than the threshold value T1. Then, in a case where the capacitance C1 is less than the threshold value T1, the processing returns to step S1, and in a case where the capacitance C1 is equal to or greater than the threshold value T1, the processing proceeds to step S4. That is, the control unit 35 waits until the capacitances C1 to C3 of all the sensor electrodes 66A to 66C become equal to or larger than the predetermined threshold values T1 to T3.

In step S4, it is determined whether the time difference Δt2 between the second time point Pt2 at which the capacitance C2 of the second sensor electrode 66B has changed and the third time point Pt3 at which the capacitance C3 of the third sensor electrode 66C has changed is longer than or equal to the determination time Jt2. Then, in a case where the time difference Δt2 is shorter than the determination time Jt2, the processing returns to step S1, and in a case where the time difference Δt2 is equal to or longer than the determination time Jt2, the processing proceeds to step S5.

In step S5, it is determined whether the time difference Δt1 between the first time point Pt1 at which the capacitance C1 of the first sensor electrode 66A has changed and the second time point Pt2 at which the capacitance C2 of the second sensor electrode 66B has changed is equal to or longer than the determination time Jt1. Then, in a case where the time difference Δt1 is shorter than the determination time Jt1, the processing returns to step S1, and in a case where the time difference Δt1 is equal to or longer than the determination time Jt1, the processing proceeds to step S6.

In step S6, it is determined whether the LED 32 is in the on (lighting-on) state. In a case where the LED 32 is in the on state, the processing proceeds to step S7, the LED 32 is turned off, and the processing returns to step S1. On the other hand, in a case where the LED 32 is in the off (lighting-off) state, the processing proceeds to step S8, the LED 32 is turned on, and the processing returns to step S1.

The touch switch 1 configured as described above has the following characteristics.

The first sensor electrode 66A and the second sensor electrode 66B whose length in the direction in which the operation unit 51 extends is longer than the length of the first sensor electrode 66A are provided, and the control unit 35 determines that the operation unit 51 has been operated when the time difference Δt1 between the first time point Pt1 at which the capacitance of the first sensor electrode 66A has changed and the second time point Pt2 at which the capacitance of the second sensor electrode 66B has changed is equal to or longer than the predetermined determination time Jt1. That is, when the time difference Δt1 between the first time point Pt1 and the second time point Pt2 is shorter than the determination time Jt1, it is determined that the malfunction is caused not by the operation of the operation unit 51 by the finger but by the electromagnetic noise. It is therefore possible to prevent erroneous determination of an operation due to irradiation of electromagnetic noise, and it is possible to prevent unintended switching of the state.

Since the first sensor electrode 66A is disposed behind the operation unit 51, an operation on the operation unit 51 can be reliably detected.

The second sensor electrode 66B has an open-ended shape surrounding the first sensor electrode 66A. As a result, as compared with a case where the first sensor electrode 66A and the second sensor electrode 66B are arranged side by side, it is possible to reduce waste of space related to arrangement and to reliably detect only a finger approaching the operation unit 51. In a case where the plurality of operation units 51 is arranged side by side, erroneous detection by the sensor electrode 66 of the adjacent operation unit 51 different from the operation target operation unit 51 can occur, but such inconvenience can be reliably prevented.

The operation unit 51 is provided with the symbol mark 52, and the first sensor electrode 66A and the second sensor electrode 66B are arranged at positions facing the symbol mark 52. As a result, since the occupant extends the hand and finger toward the symbol mark 52, the control unit 35 can reliably detect the operation of the occupant by the first sensor electrode 66A and the second sensor electrode 66B, and can reliably switch the state.

The second sensor electrode 66B has an open-ended shape surrounding the first sensor electrode 66A, and the first sensor electrode 66A includes the conductive portion 67 having a flat planar shape. Therefore, the operation on the operation unit 51 can be detected more reliably.

The third sensor electrode 66C whose length in the direction in which the operation unit 51 extends is longer than the length of the second sensor electrode 66B is provided, and the third sensor electrode 66C is configured to surround the second sensor electrode 66B. As a result, the detection range in a direction intersecting the operation unit 51 can be divided into three stages. Therefore, the control unit 35 can determine whether the operation is performed by the finger of the occupant or the malfunction caused by the electromagnetic noise on the basis of the time difference Δt1 between the first time point Pt1 at which the capacitance of the first sensor electrode 66A has changed and the second time point Pt2 at which the capacitance of the second sensor electrode 66B has changed, and the time difference Δt2 between the second time point Pt2 at which the capacitance of the second sensor electrode 66B has changed and the third time point Pt3 at which the capacitance of the third sensor electrode 66C has changed. As a result, it is possible to prevent erroneous determination of an operation due to irradiation of electromagnetic noise, and it is possible to reliably prevent unintended switching of the state.

Note that the present invention is not limited to the configuration of the above embodiment, and various modifications can be made.

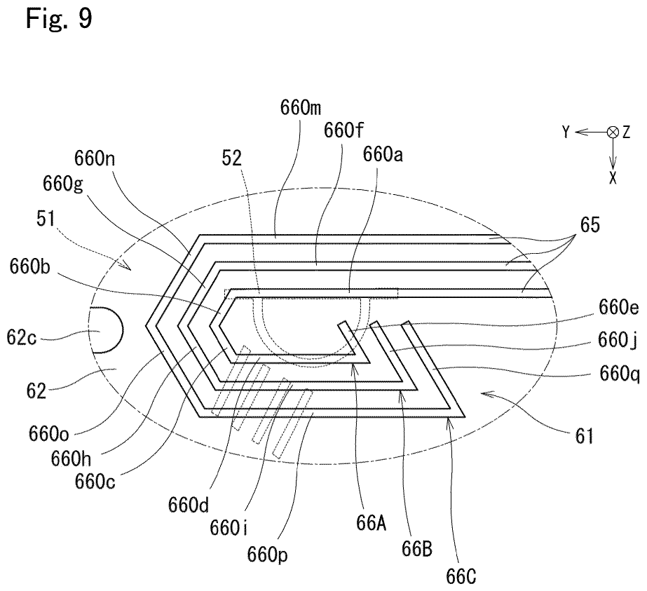

For example, as illustrated in FIG. 9, the shapes of the sensor electrodes 66A to 66C constituting the detector 61 can be changed as necessary. In the example illustrated in FIG. 9, the first sensor electrode 66A includes a first portion 660a to a fifth portion 660e, the second sensor electrode 66B includes a first portion 660f to a fifth portion 660j, and the third sensor electrode 66C includes a first portion 660m to a fifth portion 660q. Each of the first portions 660a, 660f, and 660m is connected to the connection wire 65 and extends in the vehicle width direction. The second portions 660b, 660g, and 660n are continuous with the corresponding first portions 660a, 660f, and 660m, and extend in a direction away from the first portions 660a, 660f, and 660m in the vehicle width direction obliquely toward the front side in the vehicle length direction. The third portions 660c, 660h, and 660o are continuous with the corresponding second portions 660b, 660g, and 660n, and extend in a direction approaching the first portions 660a, 660f, and 660m in the vehicle width direction obliquely toward the front side in the vehicle length direction. The fourth portions 660d, 660i, and 660p are continuous with the corresponding third portions 660c, 660h, and 660o, and extend in the vehicle width direction. The fifth portions 660e, 660j, and 660q are continuous with the corresponding fourth portions 660d, 660i, and 660p, and extend obliquely along the third portions 660c, 660h, and 660o. The first portions 660a, 660f, and 660m to the fifth portions 660e, 660j, and 660q are all located at intervals.

In the detector 61, at least the first sensor electrode 66A is only required to be disposed to face a back surface of operation unit 51. That is, the second sensor electrode 66B and the third sensor electrode 66C may be arranged at positions where the centroid C does not coincide with the center of the operation unit 51, or may be arranged side by side with the first sensor electrode 66A as long as a distance from the adjacent operation unit 51 can be secured.

The three sensor electrodes 66A to 66C constituting the detector 61 may be disposed on the operation unit 51 itself, specifically, on the back surface or a front surface of the operation unit 51 in the operation panel 50.

The detector 61 may include only the first sensor electrode 66A and the second sensor electrode 66B without the third sensor electrode 66C. The detector 61 may include four or more sensor electrodes 66.

The determination of the change in the capacitance C of the sensor electrode 66 by the control unit (determination unit) 35 may be made by an increasing gradient of the capacitance within a predetermined time instead of the threshold values T1 to T3, and a criterion of the determination can be changed as necessary.

The time point Pt at which it is determined that the capacitance C of the sensor electrode 66 has changed is not limited to the time at which the capacitance C first exceeds the threshold value T, and may be the time at which a state in which the capacitance C exceeds the threshold value T continues for a predetermined time (for example, 17 ms) or longer. The determination time point Pt may be a time at which the capacitance C first exceeds the threshold value T in a case where a state where the capacitance C exceeds the threshold value T continues for a predetermined time (for example, 17 ms) or more.

The control unit 35 may determine that the touch operation is performed by the occupant when only one of the time difference Δt1 or Δt2 becomes longer than or equal to the determination time Jt1 or Jt2. The control unit 35 may determine that the touch operation is performed by the occupant when a state in which the time differences Δt1 and Δt2 are both equal to or longer than the determination times Jt1 and Jt2 and the capacitances of the three sensor electrodes 66A to 66 C respectively exceed the threshold values T1 to T3 is maintained.

The detector 61 may include a mutual capacitance type touch sensor including a drive electrode and a measurement electrode. In other words, an aspect in which one detector 61 is constituted by two or more sensor units is also applicable to the mutual capacitance type.

The touch switch 1 is also applicable to devices other than the indoor lamp 5. That is, the touch switch may be disposed on an instrument panel of a vehicle and used for an operation unit for operating an in-vehicle device, or may be used for an operation unit of a device other than a vehicle.

### REFERENCE SIGNS LIST

1 touch switch
5 indoor lamp
10 exterior panel
11 opening
12 penetrating portion
13 penetrating portion
20 cover
30 circuit board
31 connector
32 to 34 LED
35 control unit (determination unit)
40 frame
41 to 43 penetrating portion
50 operation panel
51 operation unit
52 symbol mark
53 display unit
54 mark
60 sensor unit
61 detector
62 film base material
62a base
62b protrusion
62c positioning hole
63 ground electrode
64 conductor pattern
65 connection wire
66 sensor electrode
66A first sensor electrode (first sensor unit)
66B second sensor electrode (second sensor unit)
66C third sensor electrode (third sensor unit)
66a first portion of first sensor electrode
66b second portion of first sensor electrode
66c third portion of first sensor electrode
66d first portion of second sensor electrode
66e second portion of second sensor electrode
66f third portion of second sensor electrode
66g fourth portion of second sensor electrode
66h first portion of third sensor electrode
66i second portion of third sensor electrode
66j third portion of third sensor electrode
66k fourth portion of third sensor electrode
660a first portion of first sensor electrode
660b second portion of first sensor electrode
660c third portion of first sensor electrode
660d fourth portion of first sensor electrode
660e fifth portion of first sensor electrode
660f first portion of second sensor electrode
660g second portion of second sensor electrode
660h third portion of second sensor electrode
660i fourth portion of second sensor electrode
660j fifth portion of second sensor electrode
660m first portion of third sensor electrode
660n second portion of third sensor electrode
660o third portion of third sensor electrode
660p fourth portion of third sensor electrode
660q fifth portion of third sensor electrode
67 conductive portion
68 connecting portion
L1 length of first sensor electrode
L2 length of second sensor electrode
L3 length of third sensor electrode
R1 detection range of first sensor electrode
R2 detection range of second sensor electrode
R3 detection range of third sensor electrode
Pt1 time point at which capacitance of first sensor electrode has changed
Pt2 time point at which capacitance of second sensor electrode has changed
Pt3 time point at which capacitance of third sensor electrode has changed
Δt1 time difference between first time point Pt1 and second time point Pt2
Δt2 time difference between second time point Pt2 and third time point Pt3

1. A touch switch comprising:
an operation unit having a planar shape;
a first sensor unit that allows detection of an approach of a human body to the operation unit by a change in capacitance;
a second sensor unit that allows detection of approach of a human body to the operation unit by a change in capacitance and has a length in a direction in which the operation unit extends, the length being longer than a length in a direction in which the operation unit of the first sensor unit extends; and
a determination unit that determines that the operation unit has been operated when a time difference between a first time point at which the capacitance of the first sensor unit has changed and a second time point at which the capacitance of the second sensor unit has changed is equal to or longer than a predetermined determination time.

2. The touch switch according to claim 1, wherein at least the first sensor unit is disposed on the operation unit or at an opposing position behind the operation unit.

3. The touch switch according to claim 2, wherein the second sensor unit includes an electrode that has an open-ended shape and surrounds the first sensor unit.

4. The touch switch according to claim 3, wherein
the operation unit is provided with a mark indicating a switching function, and
the first sensor unit and the second sensor unit are disposed at positions facing the mark.

5. The touch switch according to claim 4, wherein the first sensor unit includes a conductive portion having a flat planar shape.

6. The touch switch according to claim 3, further comprising a third sensor unit having a length in a direction in which the operation unit extends, the length being longer than the length of the second sensor unit in the direction in which the operation unit extends,
wherein the third sensor unit includes an electrode that has an open-ended shape and surrounds the first sensor unit and the second sensor unit.

7. The touch switch according to claim 4, further comprising a third sensor unit having a length in a direction in which the operation unit extends, the length being longer than the length of the second sensor unit in the direction in which the operation unit extends,
wherein the third sensor unit includes an electrode that has an open-ended shape and surrounds the first sensor unit and the second sensor unit.

8. The touch switch according to claim 5, further comprising a third sensor unit having a length in a direction in which the operation unit extends, the length being longer than the length of the second sensor unit in the direction in which the operation unit extends,
wherein the third sensor unit includes an electrode that has an open-ended shape and surrounds the first sensor unit and the second sensor unit.
